(19) United States
(12) Patent Application Publication
(10) Pub. No.: US 2024/0092700 A1
(43) Pub. Date: Mar. 21, 2024

(54) METHOD FOR PRECIPITATION HARDENING OF A PIEZOCERAMIC, AND PIEZOCERAMIC

(71) Applicant: TECHNISCHE UNIVERSITÄT DARMSTADT, Darmstadt (DE)

(72) Inventors: Jürgen RÖDEL, Plochingen (DE); Jurij KORUZA, Plochingen (DE); Changhao ZHAO, Plochingen (CH)

(21) Appl. No.: 18/546,565

(22) PCT Filed: Mar. 17, 2023
(86) PCT No.: PCT/EP2022/056951

§ 371 Date: Aug. 15, 2023

(30) Foreign Application Priority Data
Mar. 18, 2021 (DE) 10 2021 106 699.9

(51) Int. Cl. C04B 41/00; C04B 41/80; H10N 30/853

(52) U.S. Cl. CPC C04B 41/0072; C04B 41/80; H10N 30/853

(57) ABSTRACT

The present invention relates to a method for precipitation hardening of a piezoceramic and to a piezoceramic.

The present invention relates to a method for precipitation hardening of a piezoceramic and to a piezoceramic.

### PRIOR ART

So-called piezoceramics are known from the prior art. They are used in numerous technical fields. One of the most important fields is the generation of ultrasound. However, the problem with known piezoceramics is that they frequently overheat and contain lead.

It is therefore the object of the present invention to specify a method with which piezoceramics can be produced that overcome the disadvantages of the prior art. It is also an object of the present invention to specify a piezoceramic which overcomes the disadvantages of the prior art.

### DESCRIPTION OF THE INVENTION

The object is achieved by the invention according to a first aspect in that a method is proposed for precipitation hardening of a piezoceramic, the method comprising:
sintering a piezoceramic, in particular a niobate, titanate or ferrite ceramic, at at least one sintering temperature;
heat-treating the sintered piezoceramic, the heat treatment comprising: adjusting the temperature of the piezoceramic from the sintering temperature to a process temperature; and
age-hardening the piezoceramic at least one age-hardening temperature, wherein the age-hardening takes place, at least at the beginning, at the process temperature as the age-hardening temperature.

The invention is therefore based on the surprising finding that the domain wall movement in the interior of the ceramic component can be significantly reduced by providing precipitates in the ceramic material. As a result, the losses are reduced and less heat is produced in the ceramic when it moves during use, i.e. expands periodically and contracts again. This significantly reduces the risk of overheating of the ceramic. The ceramic can thus also be used with higher temperatures and with higher performance. As a result, the use of the ceramic is more reliable and possible even under more demanding conditions.

In this way, the field of application of the ceramics produced using the proposed method can be expanded, namely both in terms of the application temperature and also the vibration speed and thus the supplied energy.

Preferably, precipitates in the sense of the present application are second phases in the ceramic structure, in particular within the matrix grains of the piezoceramic. The precipitates and/or the piezoceramic can be at room temperature, and in particular during the entire method for precipitation hardening described herein, in a state of aggregation of a solid body. The second phases arise entirely or partially by the heat treatment, in particular by the aging, within the scope of a precipitation process which takes place as it progresses. The composition and form of the second phases can be distinguished from the ceramic main phase (matrix), as will be explained in greater detail in particular below with reference to FIGS. 2 to 5. In comparison with mixed-in additives, precipitates are advantageously distributed more homogeneously in the ceramic. In particular, the precipitates are located in the grain interior. If necessary, a precipitate contains, in particular consists of, a material which can form by heat treatment of the sintered ceramic at a temperature below the sintering temperature. If, for example, the piezoceramic is formed of an alkali niobate, no precipitate of aluminum oxide can form by heat treatment.

Due to the heat treatment of the sintered piezoceramic according to the invention, the precipitates can be realized particularly easily and reliably.

The precipitates can be realized particularly easily by the heat treatment according to the invention, in particular after the sintering of the piezoceramic. As a result of the heat treatment according to the invention (or in other words: the thermal process), precipitates are formed in the grain interior. This results in precipitation hardening of the piezoceramic. During the age-hardening, a precipitation process of the piezoceramic is carried out in order to obtain the final structure of the precipitation-hardened piezoceramic.

The term “precipitation hardening” preferably means here that the piezoceramic has improved properties due to the produced precipitates, for example with regard to increased temperature resistance, reduced temperature generation during operation, reduced strain hysteresis, reduced polarization hysteresis and/or increased mechanical quality of the piezoceramic.

The heat treatment can be realized particularly easily. First, the piezoceramic is simply brought to a process temperature after sintering by, in particular fast, cooling or quenching, with which its age-hardening also begins. After age-hardening (which may optionally have further temperatures), the piezoceramic can then be cooled, for example.

It is particularly preferred if the heat treatment directly follows the sintering. The method can thus be carried out very efficiently.

Preferably, the temperature during the entire method is monitored according to a defined or definable temperature profile. This is particularly reliable.

A change in temperature can in principle preferably be linear, parabolic, according to another polynomial function, or exponential.

The precipitates preferably have a size smaller than the matrix grain size and/or a size of between 0.01 μm and 1 μm, preferably between 0.05 μm and 0.5 μm, preferably between 0.1 μm and 0.5 μm, and preferably between 0.2 μm and 0.4 μm.

In one embodiment, the piezoceramic can be formed in the shape of a disk, a bar, a cube, a hemisphere or a ring. Alternatively or additionally, the piezoceramic, in particular when its formed in the shape of a disk or a ring, has a thickness of at least 0.05 cm, preferably of at least 0.1 cm, preferably of at least 0.3 cm, preferably of at least 0.5 cm, preferably of at least 1 cm, preferably of at least 2 cm, preferably of at least 3 cm, preferably of at least 4 cm, preferably of at least 5 cm, preferably of at least 6 cm, and/or of at most 10 cm, preferably of at most 9 cm, preferably of at most 8 cm, preferably of at most 7 cm, preferably of at most 6 cm, preferably of at most 5 cm, preferably of at most 4 cm, preferably of at most 3 cm, preferably of at most 2 cm, preferably of at most 1 cm, preferably of at most 0.5 cm, preferably of at most 0.3 cm, preferably of at most 0.1 cm, and preferably of at most 0.05 cm. The thickness can also be between 0.05 cm and 10 cm, preferably between 1 cm and 5 cm, wherein the boundary values are preferably included or not included.

For example, one or more heating devices of one or more furnace(s), within the receptacle of which the piezoceramic is arranged, can be controlled in such a way that the piezoceramic is brought to and/or held at the relevant temperatures during the sintering and/or heat treatment. Accordingly, a single furnace having one or more heating devices, or a plurality of furnaces, each of which has one or more heating devices, can thus preferably be used.

The control of the temperature can include the setting, changing, closed-loop control and/or open-loop control of the temperature. Preferably, the target temperature specified at a point in time is set by controlling the temperature as a function of time.

The piezoceramic and/or its powdered starting material can preferably comprise or consist of: 0.8BaTiO₃-0.2CaTiO₃ and/or (Ba,Ca)TiO₃.

In one embodiment, the piezoceramic and/or its powdered starting material comprises or consists of the materials: piezoceramic from the class of lead zirconate titanate (PZT) materials with more than 50% consisting of PZT, from the class of lead magnesium niobate (PMN) with more than 50% consisting of PMN, from the class of BaTiO₃-based materials consisting of more than 50% BaTiO₃, the sodium bismuth titanate (NBT)-based piezoceramics, consisting of more than 50% NBT, from the class of alkali niobates consisting of more than 50% alkali niobates, and/or from the class of bismuth ferrite (BF)-based piezoceramics, consisting of more than 50% BF.

In one embodiment, the piezoceramic is an oxide ceramic, in particular a mixed oxide and/or an oxide with a perovskite structure. The ceramic can have one or more cationic components which in particular can comprise or consist of alkali metal, alkaline earth metal, iron, niobium, zirconium, zinc, nickel, lead, bismuth and/or titanium cations. The ceramic can have one or more anionic component(s) which can comprise or consist of oxygen anions in particular. In one embodiment, the piezoceramic comprises a cationic component A and a cationic component B. The cationic component A can, in particular, be selected from alkali metal, alkaline earth metal, lead and bismuth cations and mixtures thereof. The cationic component B can, in particular, be selected from titanium, niobium, zirconium, zinc, nickel and iron cations and mixtures thereof. Optionally, the piezoceramic has an empirical formula of ABO₃. For example, the piezoceramic can be a niobate, titanate or ferrite ceramic. In one embodiment, component A is a mixture of a plurality of alkali metal and/or alkaline earth metal cations, for example of potassium and lithium, potassium and sodium, sodium and lithium, magnesium and calcium, sodium and bismuth, potassium and bismuth, lead and lanthanum, barium and zirconium or barium and calcium.

In one embodiment, the precipitates comprise an oxide ceramic, in particular a mixed oxide and/or an oxide with perovskite structure. The precipitates differ in their chemical composition from the piezoceramic surrounding them, because they form a second phase. The precipitates can have one or more cationic components which, in particular can comprise or consist of alkali metal, alkaline earth metal, iron, niobium, zirconium, zinc, nickel, lead, bismuth and/or titanium cations. The precipitates can have one or more anionic component(s) which may comprise or consist of oxygen anions in particular. In one embodiment, the precipitates comprise a cationic component A and a cationic component B. The cationic component A can, in particular, be selected from alkali metal, alkaline earth metal, lead and bismuth cations and mixtures thereof. The cationic component B can, in particular, be selected from titanium, niobium, zirconium, zinc, nickel and iron cations and mixtures thereof. Optionally, the precipitates may comprise or consist of niobate, titanate, or ferrite. In one embodiment, component A is a mixture of a plurality of alkali metal and/or alkaline earth metal cations, for example of potassium and lithium, potassium and sodium, sodium and lithium, magnesium and calcium, sodium and bismuth, potassium and bismuth, lead and lanthanum, barium and zirconium or barium and calcium.

Another important point relates to the fact that, conventionally, lead has often been used in order to achieve comparatively good results, for example with regard to mechanical quality, deflection, and vibration speed. This is no longer necessary in the present case since the lead-free piezoceramics hardened by precipitates already have better mechanical quality and therefore less heating.

In one embodiment, the produced ceramic is therefore lead-free.

As a result, the use of lead in the ceramic can be dispensed with when the method according to the invention is used. The ceramics produced in this way are therefore environmentally friendly and, on the one hand, produce fewer problems in disposal and, on the other hand, can continue to be used without problems even under strict environmental guidelines.

However, this does not mean that lead-containing piezoceramics would not be producible with the proposed method—on the contrary. The present method can also be preferably used particularly advantageously for lead-containing piezoceramics, in order then to benefit from the other advantages of the invention.

This is because the method makes it possible to produce piezoceramics which, in particular, completely or partially meet the following advantageous criteria:
freedom from lead;
no significantly greater heating takes place at higher temperatures;
higher performance can be achieved;
better safety aspect due to a lower temperature of the ceramic during its use, and thus a lower risk of thermal depolarization of the ceramic; and
due to the reduced ceramic temperature, the solvents or electronic components catching fire can be prevented, in particular avoided.

In this case, the method according to the invention can be integrated very easily in existing methods for producing and/or processing piezoceramics and thereby supplement these conventional methods. The method according to the invention can thus be implemented very efficiently.

In addition, higher prices can be achieved on the market for lead-free and/or temperature-resistant piezoceramics. Since no lead has to be contained in the piezoceramics obtained by the method according to the invention, an enormous competitive advantage to a manufacturer may grow from corresponding piezoceramics.

The method can thus be used very advantageously, particularly in the field of ceramic production and/or further processing. The method is thus particularly interesting for the ceramics industry.

The piezoceramics obtained by the method can be used very advantageously in applications and/or devices in which piezoceramics are an important component. In particular, ultrasound technology should be mentioned here, and in particular ultrasonic welding, ultrasonic cleaning and power ultrasound, as well as corresponding devices in each case. In this respect, piezoelectric motors and piezoelectric voltage converters should also be mentioned.

The method is also particularly suitable for the production of piezoceramics which are used for cleaning devices, such as in particular in the watch industry, in the hygiene sector for medical devices, in the industrial sector, for example optics, or in devices for use in industry, such as high-power applications for cleaning or welding components. A piezoceramic produced according to the invention can accordingly be used, for example, in an ultrasonic cleaning apparatus, especially in an industrial ultrasonic cleaning apparatus.

Alternatively or additionally, it can also be provided that the adjustment of the temperature of the piezoceramic involves:
cooling the piezoceramic from the sintering temperature to the process temperature, in particular within a first time period and/or with a first temperature change rate.

For example, the cooling of the piezoceramic can involve the quenching of the piezoceramic.

Within the meaning of the present application, quenching preferably means a sudden cooling of the piezoceramic from an initial temperature to a target temperature. In this case, for example, from the sintering temperature to the process temperature. For example, quenching occurs when the rate of cooling while cooling from a single-phase region to a two-phase region is so rapid that the formation of a second phase is prevented. Quenching involves, for example, processes which either include active cooling or allow the ceramic to cool down on its own without any heat supply. Cooling, in particular quenching, can take place by means of water, oil and/or by blowing with a gas, such as ambient air.

In the case of ceramic heat treatments, the cooling rate can preferably be set to a certain value by supplying heat. The cooling rate can in particular be selected depending on the thickness of the sample.

Alternatively or additionally, it can also be provided that the adjustment of the temperature of the piezoceramic involves:
cooling the piezoceramic from the sintering temperature to an intermediate temperature, in particular within a second time period and/or with a second temperature change rate;
holding the piezoceramic at the intermediate temperature for a third time period; and/or
heating the piezoceramic from the intermediate temperature to the process temperature, in particular within a fourth time period and/or with a third temperature change rate.

If the piezoceramic is first cooled to an intermediate temperature and is then heated to the higher process temperature, the production of large quantities of, in particular, very small and thus particularly effective precipitates can also be achieved in a particularly reliable manner.

By passing through the intermediate temperature, a faster cooling can be achieved, and thus a shorter dwell time in the high-temperature range. The high-temperature range means a less well controlled and/or controllable formation of precipitates. The proposed intermediate temperature thus leads to better control of the precipitates.

For example, the cooling of the piezoceramic can involve the quenching of the piezoceramic.

For example, the intermediate temperature is between 300° C. and 1200° C., in particular from 350° C. to 1200° C., or from 400° C. to 1100° C. Optionally, the intermediate temperature is between 600° C. and 1,200° C., preferably between 700° C. and 1200° C., preferably between 800° C. and 1100° C., and preferably between 800° C. and 1000° C.

For example, the intermediate temperature is at least 300° C., at least 350° C., or at least 400° C. In one embodiment, the intermediate temperature is at least 600° C., preferably at least 700° C., preferably at least 800° C., preferably at least 900° C., preferably at least 1000° C., preferably at least 1100° C. Alternatively or additionally, the intermediate temperature is at most 1500° C., preferably at most 1400° C., preferably at most 1300° C., preferably at most 1200° C., preferably at most 1100° C., preferably at most 1000° C., preferably at most 900° C., and preferably at most 800° C.

For example, the intermediate temperature is 600° C., 700° C., 800° C., 850° C., 900° C., 950° C., 1,000° C., 1,050° C., 1,100° C., 1,150° C. or 1,200° C.

Alternatively or additionally, it can also be provided that:
(i) the sintering temperature is a temperature in the single-phase range of the solid solution of the ceramic system in the phase diagram of the piezoceramic;
(ii) the intermediate temperature is a temperature within the two-phase range of the phase diagram of the piezoceramic and/or the intermediate temperature is greater than or equal to room temperature;
(iii) the sintering temperature is greater than the process temperature;
(iv) the process temperature is greater than the intermediate temperature; and/or
(v) the process temperature is a temperature within the two-phase range of the phase diagram of the piezoceramic.

Particularly advantageous results of precipitates can be achieved with the method when the temperatures are in the mentioned ranges of the phase diagram.

The phase diagram is material-dependent. It is therefore self-evident that the ranges always refer to the phase diagram of the material used for the piezoceramic.

Without being bound to a specific theory, the inventors explain the advantageous effects in the selection of the temperatures from the stated ranges in that nucleation in the interior of the matrix grains takes place in these temperature ranges, wherein the nuclei are distributed homogeneously. Subsequently, these nuclei grow to form a desired size.

It has been found to be particularly advantageous if the sintering temperature is in the single-phase phase diagram range of the solid solution (α) of the ceramic system, and the process temperature is a temperature within the two-phase range of the phase diagram (α+β). If the process temperature is achieved via an intermediate temperature, it is optionally preferred that the intermediate temperature is also a temperature within the two-phase range of the phase diagram. For example, the intermediate temperature can be room temperature or above (but the intermediate temperature is preferably lower than the process temperature).

Within the meaning of the present application, room temperature is preferably 20° C., in particular at 101.325 kPa ambient pressure.

Alternatively or additionally, it can also be provided that the age-hardening of the piezoceramic takes place at a single age-hardening temperature, in particular, age-hardening occurs during a fifth time period and/or at the process temperature as the only age-hardening temperature.

This can be realized in a particularly simple manner, since the piezoceramic is simply kept at a constant temperature (the process temperature).

Alternatively or additionally, it can also be provided that the age-hardening of the piezoceramic occurs at two or more than two different age-hardening temperatures, in particular during a sixth time period at a first age-hardening temperature and/or during a seventh time period at a second age-hardening temperature.

If the piezoceramic is age-hardened at two (or even more) different temperatures, even better results with regard to the properties of the piezoceramic can be achieved.

Alternatively or additionally, it can also be provided that:
(i) the first age-hardening temperature corresponds to the process temperature;
(ii) the second age-hardening temperature is greater than the first age-hardening temperature,
(iii) the age-hardening begins with the sixth time period,
(iv) the age-hardening ends after the seventh time period, and/or
(v) the transition from the first to the second age-hardening temperature takes place within an eighth time period and/or with a fourth temperature change rate.

The first age-hardening temperature can represent a temperature for nucleation, and/or the second age-hardening temperature can represent a temperature for the growth of the precipitates (from the nuclei). Thus, the nuclei can be produced at a lower temperature, and the growth of the precipitates can be pursued at a higher temperature. This enables particularly effective piezoceramics to be produced in a particularly reliable manner.

Advantageously, the age-hardening temperature (or the age-hardening temperatures, in particular the first age-hardening temperature) is always more than 100° C., preferably more than 200° C., preferably more than 300° C., preferably more than 400° C., preferably more than 500° C., preferably more than 600° C., preferably more than 700° C., preferably more than 800° C., preferably more than 900° C. Alternatively or additionally, the age-hardening temperature is always less than 1600° C., preferably less than 1550° C., preferably less than 1500° C., preferably less than 1450° C., preferably less than 1400° C., preferably less than 1300° C., preferably less than 1200° C., preferably less than 1100° C., and preferably less than 1000° C.

Alternatively or additionally, it can also be provided that the process temperature and/or the first age-hardening temperature is between 900° C. and 1500° C., preferably between 1000° C. and 1400° C., preferably between 1000° C. and 1300° C., and preferably between 1100° C. and 1250° C. In an alternative embodiment, the process temperature and/or the first age-hardening temperature may be at least 500° C., at least 600° C. or at least 700° C. It may preferably be at most 1450° C. or at most 1250° C. In certain embodiments, it is from 500° C. to 1450° C., from 600° C. to 1250° C. or from 700° C. to 1250° C. Depending on the piezoceramic used, the first age-hardening temperature can also be lower, in particular between 400° C. and 1000° C. or between 500° C. and 800° C. Depending on the piezoceramic, the first age-hardening temperature can be at least 400° C. or at least 500° C.

As a result of the proposed temperature profiles, it is advantageously possible to set a temperature during the heat treatment which at least temporarily has a difference from the sintering temperature of 20° C. or more, preferably of 50° C. or more, preferably of 100° C. or more, preferably of 200° C. or more, preferably of 300° C. or more, preferably of 400° C. or more, and preferably of 500° C. or more. Preferably, this difference is 1000° C. or less, preferably 900° C. or less, preferably 800° C. or less, preferably 700° C. or less, preferably 600° C. or less, preferably 550° C. or less, preferably 300° C. or less. Thus, this difference can be, for example, from 20° C. to 1000° C., from 50° C. to 900° C., or from 100° C. to 800° C.

Preferably, the maximum temperature difference between the sintering temperature and the temperature during the heat treatment, in particular the age-hardening temperature, is at most 1000° C., preferably at most 900° C., preferably at most 800° C., preferably at most 700° C., preferably at most 600° C., preferably at most 500° C., preferably at most 400° C., and preferably at most 300° C.

Preferably, the minimum temperature difference between the sintering temperature and the age-hardening temperature is at least 10° C., preferably at least 50° C., preferably at least 100° C., preferably at least 200° C., preferably at least 300° C., preferably at least 400° C., preferably at least 500° C., and preferably at least 600° C.

A thermodynamic state which requires only one phase is advantageously present during the sintering of the piezoceramic. Alternatively or additionally, a temperature (such as the process temperature and/or the age-hardening temperature) or a temperature profile is advantageously selected during the heat treatment of the sintered piezoceramic, so that there is at least temporarily or always a temperature that is lower than the sintering temperature, for example has a difference from the sintering temperature of 20° C. or more. A sufficient thermodynamic driving force for the precipitate formation can thereby be provided.

Advantageously, the temperature during the heat treatment is always at least 500° C. or more, preferably 600° C. or more, and preferably 700° C. or more. This can reliably enable sufficient kinetics to allow diffusion of cations.

Particularly effective piezoceramics can be obtained with the mentioned temperature ranges. The boundary values of the ranges are preferably included or not included.

For example, the process temperature and/or the first age-hardening temperature is at least 300° C., at least 400° C., at least 500° C., at least 600° C., at least 700° C., at least 800° C., at least 900° C., preferably at least 1000° C., preferably at least 1100° C., preferably at least 1200° C., preferably at least 1300° C., preferably at least 1400° C., and/or at most 1500° C., preferably at most 1400° C., preferably at most 1300° C., preferably at most 1200° C., preferably at most 1100° C., and preferably at most 1000° C.

For example, the process temperature and/or the first age-hardening temperature is about 400° C., 500° C., 900° C., 950° C., 1000° C., 1,050° C., 1,100° C., 1,150° C., 1,200° C., 1,250° C., 1,300° C., 1,350° C., 1,400° C., 1,450° C. or 1,500° C.

Alternatively or additionally, it can also be provided that the second age-hardening temperature is between 1000° C. and 1600° C., preferably between 1100° C. and 1500° C., preferably between 1150° C. and 1450° C., preferably between 1200° C. and 1400° C., and preferably between 1250° C. and 1350° C. In an alternative embodiment, the second age-hardening temperature may be at least 500° C., at least 600° C., or at least 700° C. It may preferably be at most 1450° C. or at most 1250° C. In certain embodiments, it is from 500° C. to 1450° C., from 600° C. to 1250° C., or from 700° C. to 1250° C.

With the mentioned temperature ranges, particularly effective piezoceramics can be obtained—depending on the piezoceramic selected. The boundary values of the ranges are preferably included or not included.

For example, the second age-hardening temperature is at least at least 900° C., preferably at least 1000° C., preferably at least 1100° C., preferably at least 1200° C., preferably at least 1300° C., preferably at least 1400° C., preferably at least 1500° C., and/or at most 1500° C., preferably at most 1400° C., preferably at most 1300° C., preferably at most 1200° C., preferably at most 1100° C., and preferably at most 1000° C.

For example, the second age-hardening temperature is 900° C., 950° C., 1,000° C., 1,050° C., 1,100° C., 1,150° C., 1,200° C., 1,250° C., 1,300° C., 1,350° C., 1,400° C., 1,450° C. or 1,500° C.

Alternatively or additionally, it can also be provided that:
(i) the sintering of the piezoceramic comprises:
providing a compact comprising ceramic powder, wherein the ceramic powder preferably comprises starting materials suitable for the production of the piezoceramic, for example (Ba,Ca)TiO₃, BaCO₃, CaCO₃ and/or T1O₂; for example Na₂CO₃, K₂CO₃, Li₂CO₃ and/or Nb₂O₅; for example Bi₂O₃, Na₂CO₃, TiO₂, and/or BaCO₃; for example PbO, ZrO₂, and/or TiO₂; for example Bi₂O₃ and/or Fe₂O₃,
and/or
sintering the compact at the at least one sintering temperature for a ninth time period to obtain the sintered piezoceramic;
and/or
(ii) the heat treatment of the sintered piezoceramic further comprises: cooling the piezoceramic, in particular starting from the last temperature of the age-hardening of the piezoceramic, to a final temperature, in particular to room temperature, within a tenth time period and/or at a fifth temperature change rate.

The compact can comprise, for example, ceramic (powdered) raw materials. For this purpose, the ceramic raw materials are preferably mixed, calcined and/or ground. The arising piezoceramic powder is brought into the desired shape of the piezoceramic by dry pressing (or another shaping process, such as film casting) and compacted.

The sintering of the compact preferably results in the structure, namely the matrix grains which are separated by grain boundaries, being formed and the material reaching the final density.

Alternatively or additionally, it can also be provided that the piezoceramic comprises less than 1 wt. %, preferably less than 0.1 wt. %, preferably less than 0.01 wt. %, preferably less than 1000 ppm, and preferably less than 100 ppm, of lead.

The method according to the invention makes it possible to produce piezoceramics without or with only very little lead. This makes it possible to use the piezoceramics even under particularly strict regulations, such as environmental regulations.

Optionally, the ceramic comprises at least 0.1 ppm of lead.

The object is achieved by the invention according to a second aspect in that a piezoceramic is proposed, in particular produced or producible using a method according to the first aspect of the invention, wherein the piezoceramic comprises at least 1% by volume precipitates.

Particularly efficient and robust piezoceramics are characterized by a corresponding content of precipitates in the piezoceramic. Especially with the method according to the invention, precipitates in the cited value range can be realized particularly well for the first time.

The piezoceramics according to the invention have the advantageous properties which have also been described elsewhere in relation to the piezoceramics produced or producible by the method. The applications and fields of use of the piezoceramic according to the invention also correspond to those as discussed in relation to the piezoceramics produced or producible by the method. Therefore, reference can be made here to these statements in order to avoid repetitions.

Preferably, the piezoceramic comprises at least 1% by volume, preferably at least 1.5% by volume, preferably at least 2% by volume, preferably at least 2.5% by volume, preferably at least 3% by volume, preferably at least 3.5% by volume, preferably at least 4% by volume, preferably at least 4.5% by volume, preferably at least 5% by volume, preferably at least 7% by volume, preferably at least 10% by volume, preferably at least 15% by volume, and preferably at least 20% by volume of precipitates. Optionally or alternatively, the piezoceramic comprises at most 50% by volume, preferably at most 50% by volume, preferably at most 40% by volume, preferably at most 30% by volume, preferably at most 20% by volume, preferably at most 15% by volume, preferably at most 10% by volume, preferably at most 7% by volume, preferably at most 5% by volume, preferably at most 4% by volume, preferably at most 3% by volume, preferably at most 2% by volume, and preferably at most 1% by volume of precipitates. A preferred volume fraction of precipitates in the piezoceramic is from 1 to 20%, in particular from 1 to 10%.

Preferably, the piezoceramic has electromechanical and piezoelectric properties, which are particularly better than in conventional piezoceramics. Preferably, the precipitates are detectable in the piezoceramic using ceramographic and/or microscopic methods, in particular using scanning electron microscopy, transmission electron microscopy and/or piezoresponse force microscopy, in particular including the volume occupied by the precipitates in the entire ceramic volume.

This preferably means that precipitates which are not detectable by such means are not counted as the relevant precipitates.

In microscopy, a 2D surface is observed, for example, and this is preferably not the surface of the piezoceramic sample; instead, the sample is first cut. Therefore, the microscopy images also show the interior of the piezoceramic.

Preferably, the number of precipitates (per one specific area) and their size can be/is determined from the microscopy images, in particular from a plurality of images, and the volume fraction is calculated therefrom (assuming a specific three-dimensional shape, typically a spherical, needle or platelet shape).

This evaluation can optionally be supplemented, for example, by X-ray diffractometry, wherein the phase fractions can be determined by means of a refinement.

An alternative method is X-ray microtomography, wherein a 3D image of the sample can be obtained, which can then be evaluated. In this case, the two phases are preferably chemically different enough, which is generally the case with the precipitates described herein.

As a material, the piezoceramic can preferably comprise or consist of: 0.8BaTiO₃-0.2CaTiO₃ and/or (Ba,Ca)TiO₃.

In one embodiment, the piezoceramic comprises or consists of: piezoceramic from the class of lead zirconate titanate (PZT) materials with more than 50% consisting of PZT, from the class of lead magnesium niobate (PMN) with more than 50% consisting of PMN, from the class of BaTiO₃-based materials consisting of more than 50% BaTiO₃, the sodium bismuth titanate (NBT)-based piezoceramics, consisting of more than 50% NBT, from the class of alkali niobates consisting of more than 50% alkali niobates, and/or from the class of bismuth ferrite (BF)-based piezoceramics, consisting of more than 50% BF.

In one embodiment, the piezoceramic is an oxide ceramic, in particular a mixed oxide and/or an oxide with a perovskite structure. The ceramic can have one or more cationic components which, in particular can comprise or consist of alkali metal, alkaline earth metal, iron, niobium, zirconium, zinc, nickel, lead, bismuth and/or titanium cations. The ceramic can have one or more anionic component(s) which can comprise or consist of oxygen anions in particular. In one embodiment, the piezoceramic comprises a cationic component A and a cationic component B. The cationic component A can, in particular, be selected from alkali metal, alkaline earth metal, lead and bismuth cations and mixtures thereof. The cationic component B can, in particular, be selected from titanium, niobium, zirconium, zinc, nickel and iron cations and mixtures thereof. Optionally, the piezoceramic has an empirical formula of ABO₃. For example, the piezoceramic can be a niobate, titanate or ferrite ceramic. In one embodiment, component A is a mixture of a plurality of alkali metal and/or alkaline earth metal cations, for example of potassium and lithium, potassium and sodium, sodium and lithium, magnesium and calcium, sodium and bismuth, potassium and bismuth, lead and lanthanum, barium and zirconium or barium and calcium.

In one embodiment, the precipitates comprise an oxide ceramic, in particular a mixed oxide and/or an oxide with perovskite structure. The precipitates differ in their chemical composition from the piezoceramic surrounding them, because they form a second phase. The precipitates can have one or more cationic components which, in particular can comprise or consist of alkali metal, alkaline earth metal, iron, niobium, zirconium, zinc, nickel, lead, bismuth and/or titanium cations. The precipitates can have one or more anionic component(s) which may comprise or consist of oxygen anions in particular. In one embodiment, the precipitates comprise a cationic component A and a cationic component B. The cationic component A can, in particular, be selected from alkali metal, alkaline earth metal, lead and bismuth cations and mixtures thereof. The cationic component B can, in particular, be selected from titanium, niobium, zirconium, zinc, nickel and iron cations and mixtures thereof. Optionally, the precipitates may comprise or consist of niobate, titanate, or ferrite. In one embodiment, component A is a mixture of a plurality of alkali metal and/or alkaline earth metal cations, for example of potassium and lithium, potassium and sodium, sodium and lithium, magnesium and calcium, sodium and bismuth, potassium and bismuth, lead and lanthanum, barium and zirconium or barium and calcium.

In one embodiment, the ceramic is lead-free. This can be realized in a favorable and reliable manner especially with the proposed method.

Alternatively or additionally, it can also be provided that the precipitates:
(i) can be identified in scanning electron microscopy images of the piezoceramic as grains of different contrasts, determined by the atomic number of the elements, in particular arranged within the matrix grains of the piezoceramic;
and/or
(ii) can be identified in transmission electron microscopy images and/or piezoresponse force microscopy images of a piezoceramic grain of the piezoceramic by a distortion of the ferroelectric domains due to an adhesion/anchoring of the domain walls.

Alternatively or additionally, it can also be provided that the piezoceramic is an outstanding piezoceramic and, in each case compared to a reference ceramic,
(i) the bipolar polarization and/or strain hystereses of the outstanding piezoceramic is/are smaller, in particular when the hysteresis is recorded with an electric field varying between −2 kV/mm and +2 kV/mm with 1 Hz; and/or
(ii) the mechanical quality of the outstanding piezoceramic is increased;
wherein the reference ceramic is preferably produced or producible by a production method comprising:
   grinding the outstanding piezoceramic;
   pressing a compact from the synthesized, ground piezoceramic powder and
   sintering the compact, in particular without quenching and age-hardening the ceramic, in order to obtain the reference ceramic.

The improvement in the piezoceramic according to the invention is achieved in particular by the fact that the precipitates arrest the movement of the ferroelectric domain walls of the outstanding piezoceramic. This reduces the losses.

In other words: as a result of the movement of the domain walls, microscopic regions within the grains each experience a certain expansion. This adds up from the individual regions depending on the local orientation to an overall strain of the component. The movement of the domain walls leads to an internal friction, leading to losses. By reducing the movement with ceramics according to the invention, the losses are reduced.

Alternatively or additionally, it can also be provided that:
(i) the polarization hysteresis of the outstanding piezoceramic is between 10% and 80%, preferably between 20% and 70%, preferably between 30% and 70%, preferably between 40% and 70%, and/or more than 10%, preferably more than 20%, preferably more than 30%, preferably more than 40%, preferably more than 50% less than that of the reference ceramic; (ii) the strain hysteresis of the outstanding piezoceramic is between 1% and 50%, preferably between 5% and 40%, preferably between 10% and 40%, preferably between 15% and 30%, and/or more than 10%, preferably more than 20%, preferably more than 30%, preferably more than 40%, preferably more than 50% less than that of the reference ceramic;
and/or
(iii) the mechanical quality of the outstanding piezoceramic is more than 10%, more than 20%, more than 30%, more than 40% or more than 50% greater than that of the reference ceramic; in a preferred embodiment, it is event greater than that of the reference ceramic by a factor of 2, 3, 5 or 10.

For example, the polarization hysteresis of the outstanding piezoceramic is less than that of the reference ceramic by at least 5%, preferably by at least 7%, preferably by at least 10%, preferably by at least 15%, preferably by at least 20%, preferably by at least 25%, preferably by at least 30%, preferably by at least 35%, preferably by at least 40%, preferably by at least 45%, and preferably by at least 50%. In one embodiment, the polarization hysteresis of the outstanding piezoceramic is less than that of the reference ceramic by at most 80%, preferably by at most 70%, preferably by at most 60%, preferably by at most 50%, preferably by at most 45%, preferably by at most 40%, preferably by at most 30%, preferably by at most 25%, preferably by at most 20%, preferably by at most 15%, and preferably by at most 10%.

For example, the strain hysteresis of the outstanding piezoceramic is less than that of the reference ceramic by least 1%, preferably by at least 3%, preferably by at least 5%, preferably by at least 7%, preferably by at least 10%, preferably by at least 13%, preferably by at least 15%, preferably by at least 17%, preferably by at least 20%, preferably by at least 25%, preferably by at least 30%, preferably by at least 35%, preferably by at least 40%, and/or by at most 50%, preferably at most 45%, preferably by at most 40%, preferably by at most 35%, preferably by at most 30%, preferably by at most 25%, preferably by at most 20%, preferably by at most 15%, preferably by at most 10%, preferably by at most 5%, and preferably by at most 3%.

For example, the mechanical quality of the outstanding piezoceramic is greater than that of the reference ceramic by at least 5%, preferably by at least 7%, preferably by at least 10%, preferably by at least 13%, preferably by at least 15%, preferably by at least 17%, preferably by at least 20%, preferably by at least 25%, preferably by at least 30%, preferably by at least 35%, preferably by at least 40%, preferably by at least 60%, preferably by at least 80%, preferably by at least 100%, preferably by at least 200%, preferably by at least 300%, preferably by at least 500%, preferably by at least 800%, preferably by at least 900%, or by at least 1000%. In one embodiment, the mechanical quality of the outstanding piezoceramic is greater than that of the reference ceramic by at most 4000%, preferably by at most 300%, preferably by at most 2000%, preferably by at most 1000%, preferably by at most 800%, preferably by at most 800%, preferably by at most 500%, and preferably by at most 300%.

The quality can be increased particularly reliably by means of the method according to the invention. In particular, an increase by, for example, up to 4000%, up to 3000%, up to 2000% or up to 1000% can also be achieved, especially when the starting material has a relatively low quality.

### Further Aspects of the Invention

The invention thus in particular has the following advantages and features:

1. Rapid cooling of the ceramic after sintering
In particular, uncontrolled processes in the intermediate temperature range are thus prevented. The single-phase state present at higher temperatures is thus also present at low temperatures (a so-called “supersaturated solution”).

2. The fact that the sintering temperature and the process/age-hardening temperature lie in different regions of the phase diagram
This ensures in particular that no precipitates arise during sintering, but only at a lower temperature, where the kinetics are slowed down and can be better controlled.

3. The age-hardening (at one or more age-hardening temperatures) of the ceramic
In this way, in particular a certain temperature for nucleation and a temperature for the growth of these nuclei are controlled in an ideal manner.

Particularly preferably, one or more of the following features can be provided:
The sintering temperature is between 900° C. and 1300° C., or between 1400° C. and 1550° C.;
The first time period (cooling from the sintering temperature to the process temperature) is between 1 s and 1 h;
The second time period (cooling from the sintering temperature to the intermediate temperature) is between 1 s and 30 h;
The third time period (holding time at the intermediate temperature) is between 1 s and 1 month, preferably between 1 and 10 minutes;
The fourth time period (heating of intermediate temperature to process temperature) is between 1 s and 30 h;
The fifth time period (age-hardening) is between 1 minute to 100 h, preferably at a temperature of between 1100° C. and 1350° C.;
The sixth time period (first age-hardening) is between 1 minute and 100 h, preferably at a temperature of between 1100° C. and 1300° C.;
The seventh time period (second age-hardening) is between 1 minute and 100 h, preferably at a temperature of between 1200° C. and 1350° C.;
The eighth time period (transition from the first age-hardening temperature to the second age-hardening temperature) is between 1 s and 30 h;
The ninth time period (sintering) is between 10 minutes and 24 h, in particular between 30 minutes and 16 h, or between 2 h and 12 h;
and/or
The tenth time period (cooling after age-hardening) is between 1 s and 30 h.

### Further Advantageous Features of the Invention

The invention can optionally have further features which are described in greater detail below. The features can specify both the method according to the first aspect of the invention and the piezoceramic according to the second aspect of the invention, unless otherwise apparent from the context.

The heat treatment of the sintered piezoceramic advantageously generates a precipitation in the grain, in particular in the matrix grain, of the piezoceramic and/or triggers, supports, reinforces and/or improves the development thereof. This has proven to be particularly advantageous in comparison with a pure admixing of the second phase. This is because the latter is inert in addition to the matrix phase and acts in particular only in the grain boundary phase. Also, an admixture cannot distribute as homogeneously as the precipitates.

Typically, admixed components also have much larger grain diameters. In contrast to this, significantly improved material properties can be achieved with precipitates within the grain (by the interaction with the ferroelectric domain walls which are located in the grain interior).

A diffusion of cations in the grain volume (lattice) is advantageously enabled by the age-hardening (also referred to as tempering or aging) in order to produce precipitates there in the grain volume.

Advantageously, the material system of the piezoceramic is or comprises LNN, for example NaₓLi₁₋ₓNbO₃.

Advantageously, the heat treatment is a single-stage heat treatment, in particular the age-hardening temperature is kept constant. For example, the temperature (for instance the age-hardening temperature) during the optionally single-stage heat treatment is between 500° C. and 800° C. The temperature of the heat treatment (in particular the age-hardening temperature) can in particular be between 1 hour and 48 hours (for example 24 hours), preferably between 4 hours and 24 hours, preferably between 4 hours and 12 hours (for example 8 hours) or between 12 hours and 24 hours.

Advantageously, in the single-stage heat treatment, the number, the density and/or the size of the precipitates is in each case at least partially controlled by the temperature selected during the heat treatment.

The heat treatment can advantageously also be a two-stage heat treatment, in particular the age-hardening temperature is thus changed from one to another age-hardening temperature, for example continuously or discretely. For example, the temperature (for instance the first age-hardening temperature) during the two-stage heat treatment is firstly between 500° C. and 800° C.(for example 500° C.), in particular for between 12 hours and 48 hours, such as 24 hours, and then between 500° C. and 800° C. (for example 600° C.), in particular for between 0.1 hour and 12 hours, in particular for between 1 hour and 8 hours, for example for 6 hours. This two-stage heat treatment has proven to be particularly suitable for niobate piezoceramics.

In the case of the two-stage heat treatment, the first treatment stage can advantageously serve for nucleation, and/or the second treatment stage can advantageously serve to grow the precipitates (or the nuclei).

Advantageously, in the case of the two-stage heat treatment, the size of the precipitates is at least partially controlled by the selection of the duration of the second treatment stage.

Preferably, the heat treatment is always carried out at temperatures above the Curie temperature of the sintered piezoceramic.

Preferably, the mechanical quality of the piezoceramic heat-treated by the method according to the first aspect of the invention and/or the piezoceramic heat-treated according to the second aspect of the invention is 100 or more, preferably 350 or more, preferably 600 or more, preferably 850 or more, and preferably 1000 or more. Optionally, the mechanical quality may be less than 4000, less than 2000, or less than 1500.

This allows the use of such ceramics with comparatively low heat generation. The mechanical quality of a ceramic can preferably be determined in accordance with DIN EN 50324:2002-12.

Alternatively or additionally, it may also be provided that the piezoceramic has a polarization hysteresis, the two branches of which without an external electric field (that is to say at the points of intersection with the Y-axis; cf. FIG. 6a) have a vertical distance of 3 μC/cm² or more, preferably of 5 μC/cm² or more, preferably of 10 μC/cm² or more, preferably of 15 μC/cm² or more, preferably of 20 μC/cm² or more, preferably of 25 μC/cm² or more, preferably of 30 μC/cm² or more, and/or of 50 μC/cm² or less, preferably of 45 μC/cm² or less, preferably of 40 μC/cm² or less, preferably of 35 μC/cm² or less, preferably of 30 μC/cm² or less, preferably of 25 μC/cm² or less, preferably of 20 μC/cm² or less, preferably of 15 μC/cm² or less, preferably of 10 μC/cm² or less, and preferably of 5 μC/cm² or less.

For example, the polarization hysteresis may be determinable or may have been determined here with an electric field that has a frequency of 1 Hz. The polarization hysteresis can be measured, for example, by means of a Sawyer-Tower circuit, shunt method or virtual-ground method.

Alternatively or additionally, it may also provided that the piezoceramic has a strain hysteresis having a maximum strain value of 0.01% or more, preferably of 0.02% or more, preferably of 0.03% or more, preferably of 0.04% or more, preferably of 0.05% or more, preferably of 0.06% or more, preferably of 0.07% or more, and/or of 0.1% or less, preferably of 0.9% or less, preferably of 0.8% or less, preferably of 0.7% or less, preferably of 0.6% or less, preferably of 0.5% or less, preferably of 0.4% or less, preferably of 0.3% or less, and preferably of 0.2% or less.

For example, the strain hysteresis may be determinable or may have been determined with an electric field that has a frequency of 1 Hz. The strain hysteresis can be determined using a laser interferometer, using an optical sensor, using an inductive sensor (LVDT), or using a strain gauge.

Preferably, the precipitates have a size, in particular a diameter, which is 0.1% or more, 1% or more, 3% or more, preferably 5% or more, preferably 8% or more, preferably 10% or more of the grain size, in particular of the diameter of the grain. Optionally, the precipitates have a size, in particular a largest diameter, which is 20% or less, preferably 18% or less, preferably 16% or less, preferably 14% or less, preferably 12% or less, of the grain size, in particular of the largest diameter of the grain.

Preferably, the precipitates are coherent, semi-coherent and/or anisometric precipitates. The domain wall can particularly advantageously be arrested by means of anisometric precipitates. In the case of coherent precipitates, the lattice constant of the precipitate deviates only slightly (e.g., at most 2%) from the lattice constant of the surrounding matrix, and therefore the lattice planes through the interface are continuous. In the case of a semi-coherent precipitate, this only applies to one side of the interface. Anisometric precipitates are precipitates with different lengths in two or three spatial directions.

It is advantageous that the precipitates are produced in the grain. This allows particularly effective access to all domain walls. This may be due to the fact that it can thus be reliably achieved that each volume of the piezoceramic is occupied by precipitates.

With respect to the reference ceramic mentioned further above, the piezoceramic presented in Shibata et al. is one example (Kenji Shibata, Ruiping Wang, Tonshaku Tou, and Jurij Koruza, “Applications of lead-free piezoelectric materials”, mrs bulletin, 83, 612-616(2018)). A material for resonance applications is described therein with the composition 0.82(Bi_{1/2}Na_{1/2}) TiO₃-0.15BaTiO₃-0.03(Bi_{1/2}Na_{1/2})(Mn_{1/3}Nb_{2/3})O₃, and an electromechanical quality Qₘ of 500 and a piezoelectric coefficient, d₃₃ of 110 μC/N.

Advantageously, the precipitates are produced by a material that does not correspond to the main material of the piezoceramic. The “main material” is the material that, in terms of its mass fraction, has the greatest fraction of the piezoceramic.

Preferably, the piezoceramic comprises approximately one precipitate per 100 nm³, on average. In one embodiment, this precipitate density is at least 0.1 precipitates per 100 nm³, in particular at least 0.5 precipitates per 100 nm³ or at least 0.8 precipitates per 100 nm³. Optionally, this precipitate density is at most 10.0 precipitates per 100 nm³, in particular at most 3.0 precipitates per 100 nm³ or at most 1.5 precipitates per 100 nm³. In particular, this precipitation density can be 0.1 to 10.0 precipitates per 100 nm³, in particular from 0.5 to 3.0 precipitates per 100 nm³ or from 0.8 to 1.5 precipitates per 100 nm³. The invention leads in particular to a particularly homogeneous distribution of the precipitates in the piezoceramic. In one embodiment, the piezoceramic does not comprise a volume fraction of 100 nm³ with a precipitation density of more than 10 per 100 nm³. The distance between the precipitates in the piezoceramic is in particular 20 nm to 200 nm, preferably 40 nm to 180 nm, or 40 nm to 150 nm, on average. The average distance of the precipitates is the mean value of the distances of each precipitate to the three precipitates that are each closest to it.

Preferably, the “size” of a precipitate or a grain is understood to mean the maximum extent of the particular precipitate or the grain in the piezoceramic in question.

Advantageously, the proportion in percent by volume of the precipitates in a piezoceramic can be determined particularly advantageously by an evaluation of the piezoceramic by means of transmission electron microscopy, specifically in particular (for example in continuation and/or supplementation of the approach mentioned elsewhere and/or alternatively thereto) by dividing the piezoceramic into a plurality of slices of the same and/or known thickness, and by taking one or more transmission electron microscopy images for each slice and evaluating said image(s) with respect to the proportion in percent by volume of the existing precipitates. Alternatively, this evaluation can take place on the basis of images taken using a scanning electron microscope.

### BRIEF DESCRIPTION OF THE FIGURES

Further features and advantages of the invention will become apparent from the following description in which preferred embodiments of the invention are explained with reference to schematic drawings.

In the drawings:

FIG. 1a shows part of a phase diagram of a ceramic system used by way of example for the precipitation hardening according to the invention;

FIG. 1b shows an exemplary temperature profile during the method according to the invention;

FIG. 2 shows X-ray diffractograms (a) of a sintered and quenched piezoceramic and (b) of a piezoceramic produced according to the invention;

FIG. 3 shows scanning electron microscopy images (a) of a conventional piezoceramic and (b) of a piezoceramic produced according to the invention;

FIG. 4 shows transmission electron microscopy images of a piezoceramic grain (a) without and (b) with a precipitate;

FIG. 5a shows piezoresponse force microscopy images of a piezoceramic produced according to the invention with precipitates and the domain structure;

FIG. 5b shows an enlarged representation of the area marked in FIG. 5a;

FIG. 6a shows a bipolar polarization hysteresis of a sintered and quenched piezoceramic and of a piezoceramic produced according to the invention;

FIG. 6b shows a bipolar strain hysteresis of a sintered and quenched piezoceramic and of a piezoceramic produced according to the invention;

FIG. 7 shows mechanical qualities of a sintered and quenched piezoceramic as well as two piezoceramics produced according to different variants of the method according to the invention;

FIG. 8 shows part of a phase diagram of a ceramic system used by way of example for the precipitation hardening according to the invention;

FIG. 9a shows a transmission electron microscopy image of a first piezoceramic;

FIG. 9b shows a transmission electron microscopy image of a second piezoceramic;

FIG. 10 shows a transmission electron microscopy image of a third piezoceramic together with an enlarged detail;

FIG. 11a/b show an exemplary representation of the mechanical quality factor Qₘ, planar electromechanical coupling factor kₚ, and piezoelectric coefficients d₃₃ of LNN18 (from FIG. 8) samples with two-stage age-hardening (a) and single-stage age-hardening (b);

FIG. 12a shows a bipolar polarization hysteresis of piezoceramics produced according to the invention, with one-stage aging; and

FIG. 12b shows a bipolar polarization hystereses according to the invention of piezoceramics produced according to the invention with two-stage aging.

### EXAMPLES

### 1. Production of a Piezoceramic

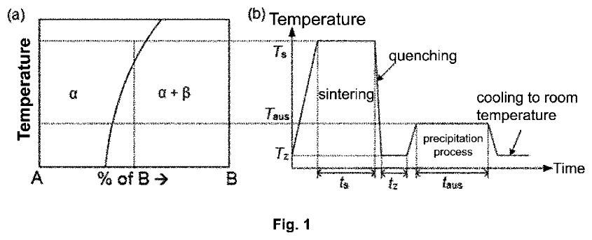

FIG. 1a shows part of the phase diagram of a ceramic system used by way of example for the precipitation hardening according to the invention. The phase diagram of FIG. 1a is such a one for a two-substance system, i.e. a ceramic material with two components. At the left edge of the diagram, the first component (A) is present as a pure substance. At the right edge of the diagram, the second component (B) is present as a pure substance.

The phase diagram is divided by a solid line into two regions. The region marked with a is the phase diagram region of the solid solution α. The region marked with α+β is the two-phase region of the phase diagram with two solid solutions α and β. The course of the solid line is dependent on the ceramic material.

Depending on the percent of substance B (cf. horizontal axis of the diagram), the single-phase region transitions into the two-phase region of the phase diagram at a temperature determined by the solid line (cf. vertical axis of the diagram).

FIG. 1b shows an exemplary temperature profile during the method according to the invention according to the first aspect of the invention. The method according to the invention is carried out with the piezoceramic, the phase diagram of which is shown in FIG. 1a.

The piezoceramic used in the method can, for example, be produced by means of solid-state synthesis and then treated according to the further method. For this purpose, the ceramic raw materials are mixed, calcined and ground. The resulting piezoceramic powder is brought into the corresponding shape by dry pressing (or another shaping process) and compacted. Thus, a compact comprising ceramic powder is provided.

This compact is subsequently sintered, wherein the structure, namely the matrix grains which are separated by grain boundaries, is formed, and the ceramic material reaches its final density. As can be seen from FIG. 1a, the method according to the invention provides, for example, that the piezoceramic is sintered to a sintering temperature Tₛ and is then sintered for a ninth time period tₛ at the sintering temperature Tₛ. The sintering temperature is in the phase diagram range of the solid solution α.

Instead of cooling the piezoceramic with a relatively slow cooling rate up to room temperature after sintering as is conventional, a specific heat treatment takes place after sintering according to the invention.

During the course of the heat treatment, the piezoceramic is quenched after the sintering. This means that it is cooled at a relatively fast cooling rate, specifically in the present case into the two-phase region of the phase diagram. The piezoceramic is quenched here to an intermediate temperature T_{z}(for example, this can be room temperature) and is held for a time period t_{z} at this temperature. As can be seen from FIG. 1a, the intermediate temperature T_{z} is in the two-phase region of the phase diagram. Subsequently, the piezoceramic is heated to a higher process temperature, which is still in the two-phase diagram. This higher process temperature is in the present case also the same as the precipitation temperature Tₐᵤₛ.

The process temperature and thus also the precipitation temperature typically depend on the particular ceramic system, and therefore on the material which comprises the piezoceramic, in particular also at the beginning in the form of the compact.

The piezoceramic is age-hardened at the precipitation temperature Tₐᵤₛ for a fifth time period tₐᵤₛ. In other words, during the time period tₐᵤₛ, the piezoceramic is kept constantly at the temperature Tₐᵤₛ. At least during this time period, the precipitation process takes place, and the end structure of the piezoceramic is formed. In this exemplary embodiment, the age-hardening is consequently carried out at only a single, constant, age-hardening temperature. Subsequently, the piezoceramic is cooled, for example to room temperature.

In this exemplary embodiment, the material of the piezoceramic can comprise or be, for example, 0.8BaTiO3-0.2CaTiO3 (BCT20). For BCT20, the following specific temperatures can be selected in the described process sequence (but also very generally within the scope of the method according to the invention) in order to obtain particularly preferred results: sintering temperature of 1,500° C. (in particular during a time period of tₛ=8 hours) and/or constant age-hardening temperature at a temperature between 1,000° C. and 1,300° C., for example 1,200° C. (in particular during a time period of tₐᵤₛ=72 hours).

In another embodiment, the sintered piezoceramic can also be quenched directly to the process temperature, i.e. without initially being brought to the intermediate temperature. Alternatively or additionally, it is also possible to carry out the precipitation process at two or even more than two precipitation temperatures. A first age-hardening temperature can then be used for example for nucleation, and a second age-hardening temperature for growth of the precipitates.

With the material BCT20 in the other embodiment (but also very generally within the scope of the method according to the invention), the first temperature can, for example, be between 1,100° C. and 1,250° C., in particular 1,200° C. (in particular during a time period of tₐᵤₛ=72 hours) and/or the second, for example, can be between 1,250° C. and 1350° C., in particular 1,300° C., (in particular during a time period of tₐᵤₛ=24 hours).

Additional pairs of materials and their temperatures are for example: material BCT18 with a sintering temperature of 1500° C. and precipitation temperature between 1100° C. and 1350° C., as well as the material NBT-BT-Zn with a sintering temperature of 1150° C. and precipitation temperature between 950° C. and 1050° C.

### 2. Characterization of a Piezoceramic According to the Invention

A piezoceramic produced by the method according to the invention can be characterized and described in greater detail in different ways. In particular, the presence of the precipitates produced by the method can be determined in various ways.

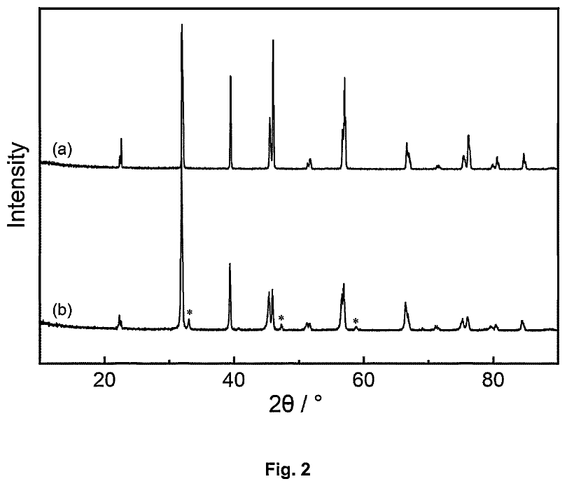

The presence of the precipitates can be determined, for example, by X-ray diffractometry. For this purpose, FIG. 2 shows X-ray diffractograms (α) of a sintered and quenched piezoceramic and (b) of a piezoceramic produced according to the invention. The example shows the piezoceramic (Ba,Ca)TiO₃. The precipitation phase is marked by an “•”.

The profile denoted by (α) in FIG. 2 corresponds to an X-ray diffractogram of the sintered and quenched sample of the exemplary piezoceramic. The characteristic denoted by (b) corresponds to an X-ray diffractogram of the sintered, quenched and age-hardened sample of the exemplary piezoceramic. The asterisk symbols denote the precipitation phase (in the case of a CaTiO₃-rich second phase), which is present only in the samples which are heat-treated and consequently age-hardened according to the invention. This shows that the specific heat treatment according to the invention leads to a pronounced formation of precipitates. In addition, there is an advantage of going above the intermediate temperature: This allows for faster cooling, and thus less dwell time in the high temperature region. The high-temperature range means a less well controlled and/or controllable formation of precipitates.

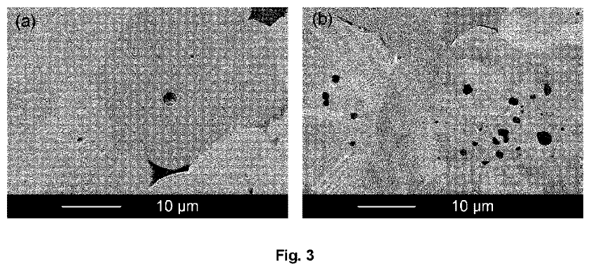

The presence of the precipitates can also be determined, for example, by scanning electron microscopy. For this purpose, FIG. 3 shows scanning electron microscopy images (a) of a conventional piezoceramic and (b) of a piezoceramic produced according to the invention. Precipitates in the samples can be seen as small black grains. It can be concluded from a comparison of the two FIG. 3 (a) and (b) that the precipitates for the piezoceramic heat-treated according to the invention are located within the matrix grains.

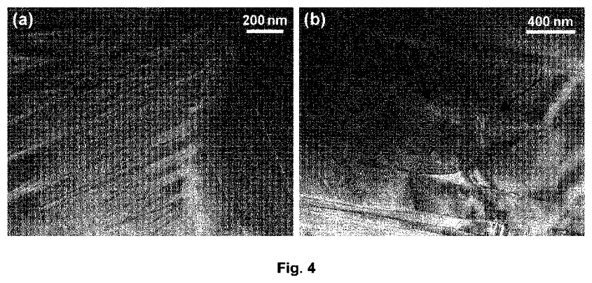

The presence of the precipitates can also be determined, for example, by transmission electron microscopy. For this purpose, FIG. 4 shows transmission electron microscopy images of a piezoceramic grain (a) without a precipitate and (b) with a precipitate. The precipitate is indicated in FIG. 4(b) by a solid arrow. The distortion of the ferroelectric domain structure in (b) is clearly discernible and is indicated by a dashed arrow. This indicates visually that the domain walls are anchored (/arrested) in a stationary manner, that is to say, their mobility is reduced. Piezoceramics produced according to the invention can consequently be determined by geometries (e.g., precipitates/distorted domains) as illustrated in FIG. 4(b).

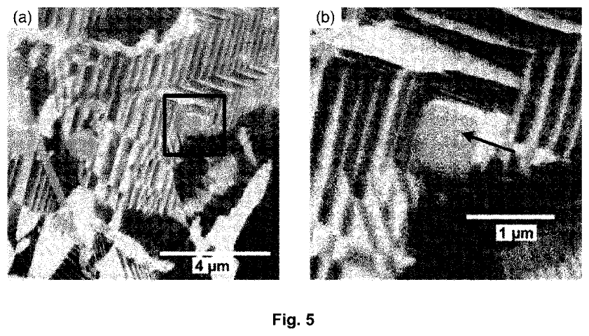

The presence of the precipitates can also be determined, for example, by piezoresponse force microscopy. For this purpose, FIG. 5 shows piezoresponse force microscopy images of a (Ba,Ca)TiO₃ piezoceramic with precipitates and the domain structure. FIGS. 5(a) and (b) are two different magnifications of the same region. The precipitate is indicated in each case by an arrow.

Atomic force microscopy can also be accordingly used to determine the presence of the precipitates.

### 3. Properties of Piezoceramics According to the Invention

The influence of the precipitates on the functional properties of the piezoceramic was quantified, inter alia, by the measurement of the electromechanical and piezoelectric properties. The precipitates arrest the movement of the ferroelectric domain walls and thus reduce the macroscopic polarization and strain. In addition, the mechanical quality, which preferably represents a reciprocal of the losses, was quantified.

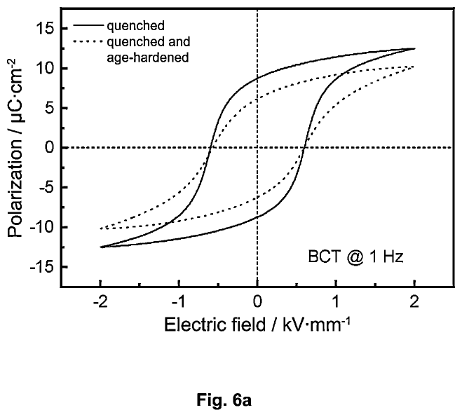

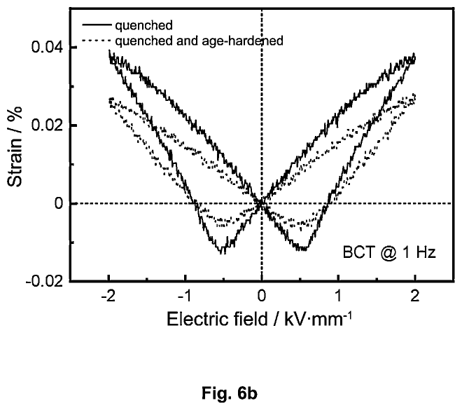

In this respect, FIG. 6a shows the bipolar polarization hysteresis, and FIG. 6b shows the bipolar expansion hysteresis, in each case of (Ba,Ca)TiO₃ piezoceramics. In this case, an electric field between +/−2 kV/mm with a frequency of 1 Hz was used. Here, a sample was sintered by the method according to the invention, quenched to room temperature, age-hardened and cooled to room temperature, and the other was quenched to room temperature directly after sintering. As a result, the effect caused by the age-hardening by the method according to the invention is illustrated particularly well.

The samples treated according to the invention (sintering, quenching, age-hardening, cooling) manifest a reduction in the polarization, the strain and the hysteresis, which illustrates the piezoelectric hardening. Thus, the polarization is reduced from about +/−12.5 μC/cm² to approximately +/−10 μC/cm² and the strain is reduced from approximately 0.04% . . . −0.015% to approximately 0.025% . . . −0.005%.

The method according to the invention therefore enables a significant reduction in the polarization, the strain and the hysteresis.

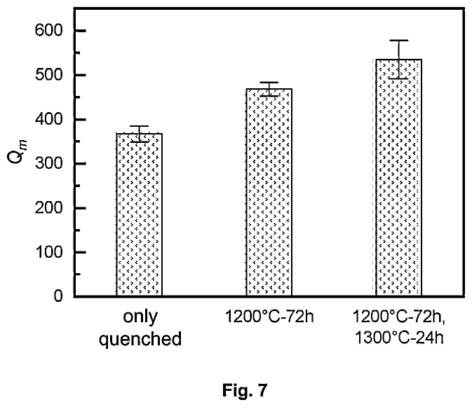

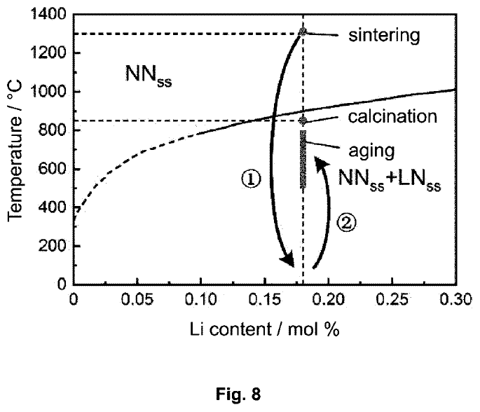

In addition, FIG. 7 shows the mechanical quality (Qₘ) of (Ba,Ca)TiO₃ piezoceramics without age-hardening (only sintered and quenched) and with age-hardening under two different conditions. If the piezoceramic is quenched to room temperature after sintering, a mechanical quality Qₘ of approximately 350 is achieved (left bar in FIG. 7, labeled “only quenched”). If the piezoceramic is age-hardened after the quenching to room temperature for 72 hours at a single constant age-hardening temperature of 1,200° C., a mechanical quality Qₘ of approximately 460 is achieved (middle bar in FIG. 7, labeled “1200° C.-72 h”). If the piezoceramic is initially age-hardened for 72 hours at an age-hardening temperature of 1,200° C. after the quenching to room temperature in order to form nuclei, and is then stored for 24 hours at an age-hardening temperature of 1,300° C. in order to grow the nuclei, a mechanical quality Qₘ of approximately 540 is achieved (right bar in FIG. 7, labeled “1200° C.-72 h, 1300° C.-24h”).

The method according to the invention therefore enables a significant increase in the mechanical quality.

The above statements regarding the figures relate to piezoceramics produced by the method according to the invention according to the first aspect of the invention. However, the statements preferably also apply equally to piezoceramics according to the invention according to the second aspect of the invention. In other words, the precipitates can then be accordingly determined in these piezoceramics. These piezoceramics then also have a reduction in the polarization, the strain and the hysteresis and an increase in the mechanical quality compared to conventional ceramics and/or a reference ceramic.

In the following, platelet-shaped precipitates for curing ceramics, in particular ferroelectric ceramics, will be discussed in greater detail.

### 4. Further Examples of Piezoceramics According to the Invention

FIG. 8 shows part of a phase diagram of a ceramic system NaₓLi₁₋ₓNbO₃ used, by way of example, for precipitation hardening according to the invention. The arrows shown therein schematically illustrate an exemplary single-stage heat treatment of the sintered ceramic, wherein the piezoceramic is quenched between the sintering and the heat treatment. NNₛₛ denotes the homogeneous single phase of the ceramic, and LNₛₛ denotes precipitates as a second phase.

A first piezoceramic of said ceramic system is sintered at 1300° C.

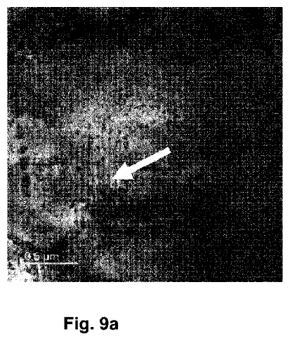

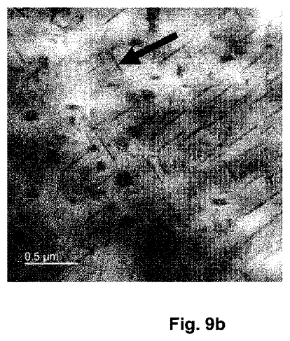

This is followed by quenching and then a single-stage heat treatment at an age-hardening temperature of 500° C. for 24 hours. FIGS. 9 and 10, 11 and 12 all relate to Li_{0.18}Na_{0.82}NbO₃.

FIG. 9a shows a transmission electron microscopy image of the piezoceramic after the first age-hardening at 500° C. for 24 hours. A plurality of point-like features can be seen therein, which identify the precipitate nuclei. One of these precipitate nuclei is also marked by an arrow.

FIG. 9b shows a transmission electron microscopy image of the piezoceramic, after the first age-hardening at initially 500° C. for 24 hours and then a second age-hardening for 6 hours at 600° C. The precipitates produced by the age-hardening are discernible as elongate structures. An arrow indicates one of the long edges of the anisometric precipitates in this case.

Clearly, the second treatment stage, that is to say, the application of a two-stage heat treatment, supports the formation of precipitates in the grain (1st step), in particular its growth (2nd step).

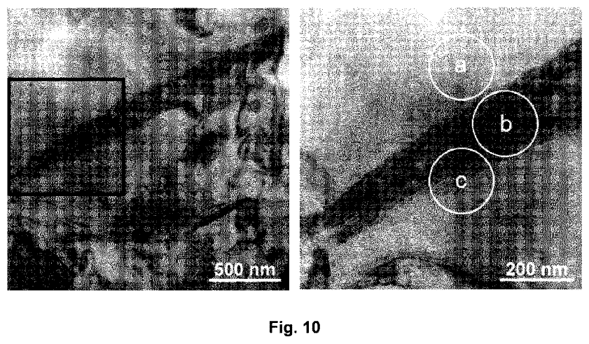

FIG. 10 shows transmission electron microscopy images of the piezoceramic as in FIG. 9, but after single-stage age-hardening at 700° C. after 8 hours (left part of the figure). A platelet-shaped LiNbO₃ precipitate can be seen here.

In the right part of FIG. 10, the region marked in the left part is shown as an enlarged detail. The precipitate can be recognized particularly well here. Three regions are marked in the detail. The region A represents the matrix grain. The region B represents the precipitate. The region C here represents the phase boundary between the precipitate and the matrix grain.

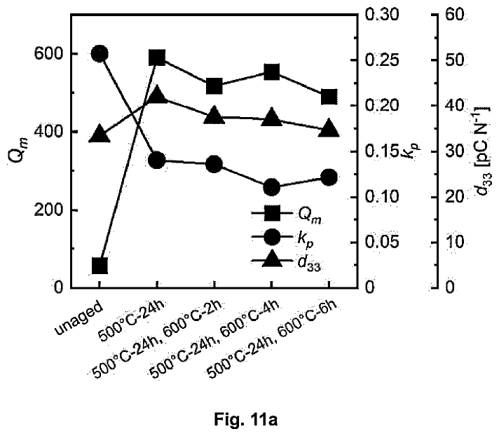

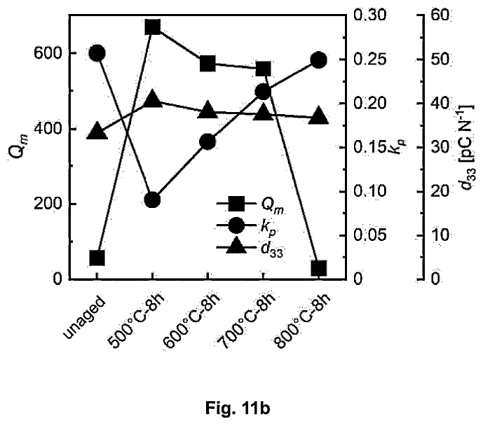

FIG. 11 a) shows the characteristic values of the two-stage age-hardening, namely first stage at 500° C. and second stage for different times at 600° C. In particular, the mechanical quality is important here, which increases by more than a factor of ten.

In particular, the electromechanical quality factor, Qₘ, is 55 for the unaged system (i.e. without the heat treatment), but 631 for the sample aged at 500° C. for 24 hours. It should also be noted that the piezoelectric coefficient is hardly changed by the treatments and the electromechanical coupling factor is reduced, but not very much.

By comparison, the single-stage age-hardening is shown in FIG. 11b). There, the same characteristic values as in FIG. 11a) are shown, but after single-stage age-hardening. In this case, the electromechanical coupling factor no longer decreases greatly at higher temperatures.

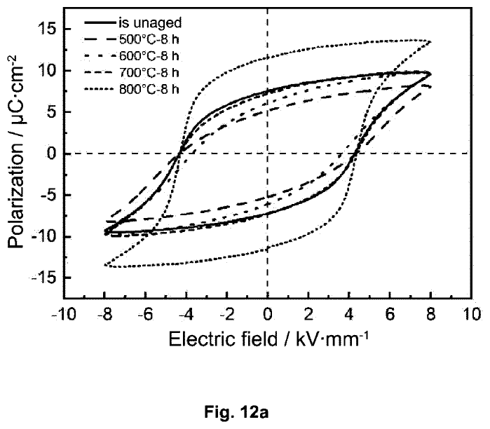

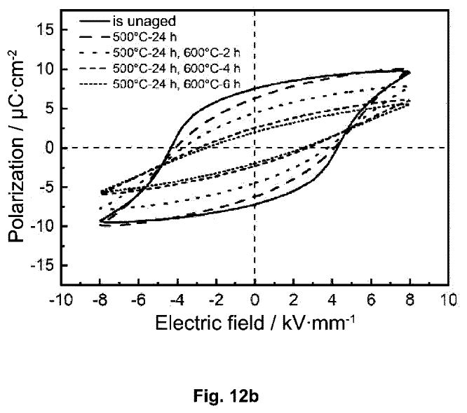

FIGS. 12a and b show the polarization curves of the different heat-treated (12a: single-stage heat treatment, 12b: two-stage heat treatment) piezoceramics.

The features disclosed in the preceding description, in the claims and in the drawings can be essential for the invention in their various embodiments both individually and in any combination.

### LIST OF REFERENCE SIGNS

Tₛ sintering temperature
Tₐᵤₛ age-hardening temperature
T_{z} intermediate temperature
tₛ time period of the sintering
tₐᵤₛ time period of the age-hardening
t_{z} time period
α single-phase region of the phase diagram
α+β two-phase region of the phase diagram

1. A method for precipitation hardening of a piezoceramic, the method comprising:
sintering a piezoceramic at least one sintering temperature;
heat-treating the sintered piezoceramic, the heat treatment comprising:
adjusting the temperature of the piezoceramic from the sintering temperature to a process temperature; and
age-hardening the piezoceramic at least one age-hardening temperature, wherein the age-hardening takes place, at least at the beginning, at the process temperature as the age-hardening temperature;
wherein precipitates are formed in the grain interior due to the heat treatment.

2. The method according to claim 1, wherein the adjustment of the temperature of the piezoceramic comprises:
cooling the piezoceramic from the sintering temperature to the process temperature, in particular within a first time period and/or with a first temperature change rate.

3. The method according to claim 1, wherein the adjustment of the temperature of the piezoceramic comprises:
cooling the piezoceramic from the sintering temperature to an intermediate temperature, in particular within a second time period and/or with a second temperature change rate;
holding the piezoceramic at the intermediate temperature for a third time period;
and/or
heating the piezoceramic from the intermediate temperature to the process temperature, in particular within a fourth time period and/or with a third temperature change rate.

4. The method according to claim 1, wherein:
(i) the sintering temperature is a temperature in the single-phase range of the solid solution of the ceramic system in the phase diagram of the piezoceramic;
(ii) the intermediate temperature is a temperature within the two-phase range of the phase diagram of the piezoceramic and/or the intermediate temperature is greater than or equal to room temperature;
(iii) the sintering temperature is greater than the process temperature;
(iv) the process temperature is greater than the intermediate temperature;
and/or
(v) the process temperature is a temperature within the two-phase range of the phase diagram of the piezoceramic.

5. The method according to claim 1, wherein:
the age-hardening of the piezoceramic takes place at a single age-hardening temperature, in particular the age-hardening during a fifth time period and/or at the process temperature as the only age-hardening temperature.

6. The method according to claim 1, wherein:
the age-hardening of the piezoceramic occurs at two or more than two different age-hardening temperatures, in particular during a sixth time period at a first age-hardening temperature and/or during a seventh time period at a second age-hardening temperature.

7. The method according to claim 6, wherein:
(i) the first age-hardening temperature corresponds to the process temperature;
(ii) the second age-hardening temperature is greater than the first age-hardening temperature,
(iii) the age-hardening begins with the sixth time period,
(iv) the age-hardening ends after the seventh time period,
and/or
(v) the transition from the first to the second age-hardening temperature takes place within an eighth time period and/or with a fourth temperature change rate.

8. The method according to claim 1, wherein the process temperature and/or the first age-hardening temperature is from 500° C. to 1450° C.

9. The method according to claim 1, wherein the second age-hardening temperature is from 600° C. to 1450° C.

10. The method according to claim 1, wherein:
(i) the sintering of the piezoceramic comprises:
providing a compact comprising ceramic powder, wherein the ceramic powder has suitable starting materials for producing the piezoceramic;
and/or
sintering the compact at the at least one sintering temperature for a ninth time period to obtain the sintered piezoceramic;
and/or
(ii) the heat treatment of the sintered piezoceramic further comprises: cooling the piezoceramic, in particular starting from the last temperature of the age-hardening of the piezoceramic, to a final temperature, in particular to room temperature, within a tenth time period and/or at a fifth temperature change rate.

11. The method according to claim 1, wherein the piezoceramic comprises less than 1 wt. %, preferably less than 0.1 wt. %, preferably less than 0.01 wt. %, preferably less than 1000 ppm, preferably less than 100 ppm, of lead.

12. A piezoceramic, in particular produced or producible by a method according to claim 1, wherein the piezoceramic comprises at least 1% by volume of precipitates.

13. The piezoceramic according to claim 12, wherein the precipitates:
(i) can be identified in scanning electron microscopy images of the piezoceramic as precipitates of different contrasts determined by the atomic number of the elements, in particular arranged within the matrix grains of the piezoceramic;
and/or
(ii) can be identified in transmission electron microscopy images and/or piezoresponse force microscopy images of a piezoceramic grain of the piezoceramic by a distortion of the ferroelectric domains by an adhesion/anchoring of the domain walls.

14. The piezoceramic according to claim 12, wherein the piezoceramic is an outstanding piezoceramic and, in each case compared to a reference ceramic,
(i) the bipolar polarization and/or strain hystereses of the outstanding piezoceramic is/are smaller, in particular when the hysteresis is recorded with an electric field varying between −2 kV/mm and +2 kV/mm with 1 Hz;
and/or
(ii) the mechanical quality of the outstanding piezoceramic is increased;
wherein the reference ceramic is preferably produced or producible by a production method comprising: grinding the outstanding piezoceramic; pressing a compact from the synthesized, ground piezoceramic powder and sintering the compact, in particular without quenching; and age-hardening the ceramic in order to obtain the reference ceramic.

15. The piezoceramic according to claim 14, wherein:
(i) the polarization hysteresis of the outstanding piezoceramic is between 10% and 80%, preferably between 20% and 70%, preferably between 30% and 70%, preferably between 40% and 70%, and/or more than 10%, preferably more than 20%, preferably more than 30%, preferably more than 40%, preferably more than 50% less than that of the reference ceramic;
(ii) the strain hysteresis of the outstanding piezoceramic is between 1% and 50%, preferably between 5% and 40%, preferably between 10% and 40%, preferably between 15% and 30%, and/or more than 10%, preferably more than 20%, preferably more than 30%, preferably more than 40%, preferably more than 50% less than that of the reference ceramic;
and/or
(iii) the mechanical quality of the outstanding piezoceramic is more than 10%, more than 20%, more than 30%, more than 40% or more than 50% greater than that of the reference ceramic.

16. The piezoceramic according to claim 12, wherein the piezoceramic has a mechanical quality of 100 or more, preferably 300 or more, preferably 800 or more, and preferably 1000 or more.

17. The piezoceramic according to claim 12, wherein the piezoceramic has a polarization hysteresis, the two branches of which without an external electric field have a vertical distance of 3 μC/cm² or more, preferably of 5 μC/cm² or more, preferably of 10 μC/cm² or more, preferably of 15 μC/cm² or more, preferably of 20 μC/cm² or more, preferably of 25 μC/cm² or more, preferably of 30 μC/cm² or more, and/or of 50 μC/cm² or less, preferably of 45 μC/cm² or less, preferably of 40 μC/cm² or less, preferably of 35 μC/cm² or less, preferably of 30 μC/cm² or less, preferably of 25 μC/cm² or less, preferably of 20 μC/cm² or less, preferably of 15 μC/cm² or less, preferably of 10 μC/cm² or less, and preferably of 5 μC/cm² or less.

18. The piezoceramic according to claim 12, wherein the piezoceramic has a strain hysteresis having a maximum strain value of 0.01% or more, preferably of 0.02% or more, preferably of 0.03% or more, preferably of 0.04% or more, preferably of 0.05% or more, preferably of 0.06% or more, preferably of 0.07% or more, and/or of 0.1% or less, preferably of 0.9% or less, preferably of 0.8% or less, preferably of 0.7% or less, preferably of 0.6% or less, preferably of 0.5% or less, preferably of 0.4% or less, preferably of 0.3% or less, and preferably of 0.2% or less.
